(19) United States
(12) Patent Application Publication
(10) Pub. No.: US 2025/0311491 A1
(43) Pub. Date: Oct. 2, 2025

(54) LIGHT-EMITTING DIODE AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Jingjing LI, Tianjin (CN); Huanshao KUO, Tianjin (CN); Yuren PENG, Tianjin (CN)

(21) Appl. No.: 19/095,139

(22) Filed: Mar. 31, 2025

(30) Foreign Application Priority Data
Apr. 2, 2024 (CN) 2024103970520

(51) Int. Cl. H10H 20/856; H10H 20/816

(52) U.S. Cl. CPC H10H 20/856; H10H 20/816

(57) ABSTRACT

A light-emitting diode and a light-emitting device are provided. In the light-emitting diode, a semiconductor epitaxial stacking layer is formed with a mesa structure, and a current spreading layer is formed in a region of the mesa structure and an edge region of a periphery of the mesa structure. The current spreading layer in the edge region is used as an etching stop layer. When the semiconductor epitaxial stacking layer is etched to form the mesa structure, the current spreading layer in a cutting region outside the mesa structure is used as the etching stop layer. During an etching process, an ICP signal can be accurately cut off when the current spreading layer is identified, so that the etching accurately stops after the semiconductor epitaxial stacking layer is etched to prevent a contact interface between the exposed semiconductor epitaxial stacking layer and a transparent dielectric layer to form a side etching gap.

### CROSS-REFERENCE TO RELATED APPLICATION

This application claims priority to Chinese Patent Application No. 202410397052.0, filed on Apr. 2, 2024. The entire contents of the above-mentioned application are incorporated herein by reference.

### TECHNICAL FIELD

The disclosure relates to the field of semiconductor manufacturing technologies, and more particularly to a light-emitting diode and a light-emitting device.

### BACKGROUND

A light-emitting diode (LED) is a semiconductor device that emits light using the energy released by the combination of carriers. Due to its advantages of high luminous intensity, high efficiency, small size and long service life, it is considered to be one of the most potential light sources at present.

LEDs in the related art include lateral LEDs and vertical LEDs. The vertical LEDs set electrodes on a top and a bottom of a chip, respectively, and make a current flow vertically through the chip. Compared with the lateral LEDs, the vertical LEDs can effectively improve the technical problems of light absorption, current congestion, or poor heat dissipation caused by an epitaxial growth substrate. When the electrode at the top of the chip is injected with current, the current will be transmitted from the electrode to a number of current transmission blocks located in the chip, and then from the current transmission blocks to the electrode at the bottom of the chip, so as to ensure that the current distribution is uniform and avoid current aggregation.

For vertical LED chips, in order to improve the luminous efficiency, a patterned current spreading layer is usually designed in a light-emitting region to reduce the light absorption of an ohmic contact layer and the current spreading layer. In a process of core formation, a semiconductor epitaxial stacking layer needs to be etched to form the light-emitting region. However, no structure similar to the current spreading layer is formed in an etched region of the semiconductor epitaxial stacking layer, which can be used as an etching stop layer. Therefore, when etched to an insulation layer below the semiconductor epitaxial stacking layer, etching gas will etch the semiconductor epitaxial stacking layer along an edge of the light-emitting region to a side thereof, causing damage to the semiconductor epitaxial stacking layer and affecting the luminous effect. More seriously, a side etching gap will be formed at an interface between the exposed semiconductor epitaxial stacking layer and the insulation layer in the light-emitting region. On the one hand, the side etching gap will cause the subsequent insulation protection layer to be poorly covered at the location. On the other hand, in the subsequent wire bonding process, the uneven stress at the position of the side etching gap will cause the semiconductor epitaxial stacking layer to peel off, resulting in device failure. Therefore, how to prevent the side of the semiconductor epitaxial stacking layer from being etched while ensuring the current transmission effect is one of the technical problems to be solved by those skilled in the related art.

### SUMMARY

Aiming at the shortcomings and defects in the etching of semiconductor epitaxial stacking layer of LED chips in the related art, the disclosure provides a light-emitting diode and a light-emitting device. In the light-emitting diode of the disclosure, a patterned current spreading layer is not only formed in a region of a mesa structure, but also in an edge region of the semiconductor epitaxial stacking layer. The current spreading layer formed in the edge region is used as an etching stop layer when the etched semiconductor epitaxial stacking layer forms the mesa structure, and an inductively coupled plasma (ICP) signal can be accurately cut off to the current spreading layer there, preventing a side of the semiconductor epitaxial stacking layer from being etched, thereby improving the yield of the structure.

According to an aspect of the disclosure, a light-emitting diode is provided, including: a semiconductor epitaxial stacking layer, a current spreading layer, an ohmic contact layer, a transparent dielectric layer, and a reflective layer.

The semiconductor epitaxial stacking layer has a first surface and a second surface opposite to each other. The semiconductor epitaxial stacking layer includes: a first conductive type semiconductor layer, an active layer and a second conductive type semiconductor layer along a direction from the first surface to the second surface. The first surface is a light-emitting surface, the semiconductor epitaxial stacking layer forms a mesa structure, and the mesa structure is a light-emitting region of the light-emitting diode.

The current spreading layer is located on a side of the second surface of the semiconductor epitaxial stacking layer. The current spreading layer includes a first part formed in a corresponding region of the mesa structure and a second part formed in an edge region of a periphery of the mesa structure, the first part is formed as patterned structures, and the patterned structures are platform regions.

The ohmic contact layer is located on a side of the platform regions facing away from the second surface.

The transparent dielectric layer is located on a side of the ohmic contact layer facing away from the semiconductor epitaxial stacking layer and fills recessed regions, and the transparent dielectric layer defines multiple openings to form multiple conductive through-holes.

The reflective layer is disposed on the transparent dielectric layer and filled into the multiple conductive through-holes to form an electrical connection with the ohmic contact layer.

As mentioned above, the current spreading layer is not only formed in the region of the mesa structure, but also in the edge region of the mesa structure. The current spreading layer in the edge region serves as the etching stop layer when the semiconductor epitaxial stacking layer is etched to form the mesa structure. Therefore, when the semiconductor epitaxial stacking layer is etched to form the mesa structure, the ICP signal can be accurately cut off to the current spreading layer there, preventing a side of the semiconductor epitaxial stacking layer from being etched, thereby improving the yield of the structure.

In an embodiment, a distance D1 between an edge of the mesa structure and an outer edge of the second part of the current spreading layer on a projection along the direction of the first surface to the second surface, a width of the second part of the current spreading layer is D2, and the width D2 is greater than or equal to the distance D1.

In an embodiment, a difference between the width D2 and the distance D1 is in a range of 1 micrometer (μm) and 20 μm.

As mentioned above, the width of the current spreading layer in the edge region is greater than the width of the edge region, that is, the current spreading layer in the edge region extends inward from the edge region to a lower part of the mesa structure, thus further protecting a side wall of the mesa structure from etching during the process of etching the semiconductor epitaxial stack.

In an embodiment, the light-emitting diode further includes a protective layer formed on a side wall and a part of the surface of the mesa structure and covering the edge region of the mesa structure.

In an embodiment, a projection of the platform regions of the first part of the current spreading layer on the first surface does not coincide with a projection of the protective layer on the first surface.

The protective layer can cover the side wall of the mesa structure completely and uniformly, and improve the protection of the semiconductor epitaxial stacking layer.

In an embodiment, a distance between geometric centers of any adjacent two of the platform regions of the first part is equal.

As mentioned above, the distance between the geometric centers of adjacent platform regions in the current spreading layer of the defined mesa structure is equal, that is, the geometric center of any platform region is a center of a circle, the distance between the geometric centers of adjacent platform regions is a radius of the circle, and the centers of adjacent platform regions are on the circle. Therefore, the adjacent platform regions form a complementary pattern when the current expands. Taking one platform region as an example, the overlapping area of current expansion between any adjacent platform regions is equal, thus achieving the effect of uniform current diffusion. In addition, the formation of the platform regions correspondingly reduces the content of the current spreading layer (such as gallium phosphide, abbreviated as GaP), which can reduce the light absorption of the current spreading layer and increase the light extraction rate of the chip.

In an embodiment, a cross-section of each platform region of the first part is circular or regular polygon.

The cross-section of the platform region is circular or regular polygon to ensure the uniform diffusion of current from it to the periphery.

In an embodiment, a distance D3 between geometric centers of any adjacent two of the platform regions of the first part is in a range of 10 μm to 30 μm.

The above limitation of the spacing distance between the geometric centers of adjacent platform regions can ensure the uniform superposition of the current diffusion in adjacent platform regions, thus ensuring the uniformity of the current diffusion in any region.

In an embodiment, a distance between geometric centers of any adjacent two of the platform regions of the first part is D3, with the geometric center of any one of the platform regions as a center of a circle and the distance D3 as a radius of the circle, and geometric centers of 2k platform regions is located on the circle, where k is a natural number greater than or equal to 1.

In an embodiment, a cross-section of each platform region is a circle in shape, and a distance D3 between geometric centers of any adjacent two of the platform regions is in a range of 1.2 to 3.2 times a diameter of the circle.

In an embodiment, a projection area of the platform regions of the first part on the second surface is in a range of 5% to 50% of a projection area of the mesa structure on the second surface.

The above area ratio of the platform regions ensures the uniform diffusion of the current while ensuring the maximum reduction of the absorption of the light emitted by the chip.

As mentioned above, by defining the distance between two adjacent platform regions and the relationship between the distance and the diameter of the platform region, the distribution of the platform regions is optimized according to the above area ratio of the platform regions, thus ensuring the uniform diffusion of the current while ensuring the maximum reduction of the absorption of the light emitted by the chip.

In an embodiment, the recessed regions are formed among the platform regions, and a depth of each recessed region is in a range of ⅓ to ⅔ of a thickness of the current spreading layer.

In an embodiment, the light-emitting diode further includes a first electrode located on a side of the first surface and electrically connected to the first conductive type semiconductor layer. The first electrode includes a pad electrode and expansion electrodes, the expansion electrodes are distributed on the side of the first surface, and when projected toward the first surface, a projection of the expansion electrodes and a projection of the pad electrode do not coincide with a projection of the first part of the current spreading layer.

In an embodiment, a cross-section of each platform region is a circle in shape, and a minimum distance between the projection of the expansion electrodes and a projection of geometric centers of the platform regions is in a range of 1.2 to 3.2 times a diameter of the circle.

In an embodiment, the light-emitting diode further includes: a substrate, a metal bonding layer, and a second electrode. The substrate is located on a side of the reflective layer facing away from the second surface. The metal bonding layer is located between the substrate and the reflective layer. The second electrode is located on a side of the substrate facing away from the second surface and is electrically connected with the second conductive type semiconductor layer.

In an embodiment, side walls of the platform regions are vertical side walls.

In an embodiment, side walls of the platform regions are inclined side walls.

In an embodiment, an opening size of a side of the platform regions facing away from the second surface is greater than a bottom size of a side of the platform regions close to the second surface.

The side walls of the platform regions of the current spreading layer can also be designed according to the specific structure of the LED chip, thereby increasing the applicability of the platform regions in different LED chips.

According to another aspect of the disclosure, a light-emitting device is provided, including a circuit board and at least one light-emitting element located on the circuit board. The at least one light-emitting element includes at least one light-emitting diode of the disclosure.

As mentioned above, the light-emitting diode and the light-emitting device of the disclosure has the following technical effects.

In the light-emitting diode of the disclosure, the semiconductor epitaxial stacking layer forms the mesa structure, and the current spreading layer is simultaneously formed in the region of the mesa structure of the light-emitting diode and the edge region of the periphery of the mesa structure. The current spreading layer in the edge region can be used as the etching stop layer when the etched semiconductor epitaxial stacking layer forms the above mesa structure. During the etching process, the current spreading layer can be identified to accurately cut off the ICP signal. The etching accurately stops after the etching of the semiconductor epitaxial stacking layer to prevent the formation of a side etching gap at the contact interface between the exposed semiconductor epitaxial stacking layer and the insulation layer (such as the transparent dielectric layer) after etching. Therefore, it can effectively improve the coverage of the protective layer on the side wall of the mesa structure, but also improve the force uniformity of the semiconductor epitaxial stacking layer during subsequent wiring, prevent the semiconductor epitaxial stacking layer stripping, and improve the yield of the light-emitting diode.

In addition, the distance between the geometric centers of adjacent platform regions in the current spreading layer, especially in the region of the mesa structure, is equal, that is, the geometric center of any platform region is the center of the circle, the distance between the geometric centers of adjacent platform regions is the radius of the circle, and the centers of adjacent platform regions are on the circle. Therefore, the adjacent platform regions form the complementary pattern when the current expands. Taking one platform region as an example, the overlapping area of current expansion between any adjacent platform regions is equal, thus achieving the effect of uniform current diffusion. In addition, the formation of the platform regions correspondingly reduces the content of the current spreading layer (such as GaP), which can reduce the light absorption of the current spreading layer and increase the light extraction rate of the chip.

At the same time, different depths of the recessed regions and side wall types of the platform regions can also be designed according to different types of LED chips or different semiconductor materials, so that the applicability of the platform regions is increased.

### BRIEF DESCRIPTION OF DRAWINGS

The features and advantages of the disclosure will be more clearly understood by reference to the accompanying drawings, which are given by way of illustration and are not to be construed as limiting the disclosure in any way.

FIG. 1 illustrates a schematic structural diagram of a light-emitting element in related art.

FIG. 2 illustrates a schematic structural diagram of a light-emitting diode according to an embodiment 1 of the disclosure.

FIG. 3 illustrates a schematic structural diagram of a light-emitting diode according to an optional implementation of the embodiment 1 of the disclosure.

FIG. 4 illustrates a schematic structural diagram from perspective of a top view of the light-emitting diode illustrated in FIG. 2 along a direction of a first surface to a second surface.

FIG. 5A illustrates a schematic structural diagram of a light-emitting diode according to another optional implementation of the embodiment 1 of the disclosure.

FIG. 5B illustrates a schematic structural diagram from perspective of a top view of the light-emitting diode along a direction from a first surface to a second surface illustrated in FIG. 5A.

FIG. 6 illustrates a schematic structural diagram of a light-emitting diode according to still another optional implementation of the embodiment 1 of the disclosure.

FIG. 7 illustrates a schematic structural diagram of a current spreading layer of a light-emitting diode according to an embodiment 2 of the disclosure.

FIG. 8 illustrates a schematic structural diagram of a distribution of platform regions of the current spreading layer illustrated in FIG. 7.

FIG. 9 illustrates a schematic structural diagram of a current spreading layer of the light-emitting diode according to an embodiment 3 of the disclosure.

FIG. 10 illustrates a schematic flowchart of a method for manufacturing a light-emitting diode according to an embodiment 4 of the disclosure.

FIG. 11 illustrates a schematic structural diagram of forming a semiconductor epitaxial stacking layer on a growth substrate.

FIG. 12 illustrates a schematic structural diagram of a structure after forming a patterned current spreading layer on the structure illustrated in FIG. 11.

FIG. 13 illustrates a schematic structural diagram of a structure forming a transparent dielectric layer on the structure illustrated in FIG. 12.

FIG. 14 illustrates a schematic structural diagram of a structure after bonding a substrate on the structure illustrated in FIG. 13.

FIG. 15 illustrates a schematic structural diagram of a structure after removing the growth substrate.

FIG. 16 illustrates a schematic structural diagram of an etched semiconductor epitaxial stacking layer forming a mesa structure.

FIG. 17 illustrates a schematic structural diagram of a light-emitting device according to an embodiment 5 of the disclosure.

### DESCRIPTION OF REFERENCE SIGNS

10-LED chip; 111-first semiconductor layer; 112-active layer; 113-second semiconductor layer; 12-insulation layer; 13-current expansion layer; 14-gap; 15-protection layer;
100-light-emitting diode; 1010-mesa structure; 1020-marginal region; 101-semiconductor epitaxial stacking layer; 1011-first conductive type semiconductor layer; 1012-second conductive type semiconductor layer; 1013-active layer; 102-current spreading layer; 1021-platform region of a first part; 1022-second part; 1023-recessed region; 1021-1-first circular platform region; 1021-2-second circular platform region; 1021-3-third circular platform region; 1021-4-circumference; 103-transparent dielectric layer; 1030-conductive through-hole; 104-reflective layer; 105-bonding layer; 106-substrate; 108-first electrode; 1081-pad electrode; 1082-expansion electrode; 107-second electrode; 109-protective layer; 110-first surface; 120-second surface; 111-ohmic contact layer; and
200-light-emitting device; 201-circuit board; 202-light-emitting unit; 203-wire layer;
300-growth substrate.

### DETAILED DESCRIPTION OF EMBODIMENTS

In order to make purposes, technical solutions and advantages of embodiments of the disclosure clearer, the technical solutions in the embodiments of the disclosure will be described clearly and completely in combination with the drawings attached to the embodiments of the disclosure. Apparently, the illustrated embodiments are a part of the embodiments of the disclosure, but not all of the whole embodiments.

In the following embodiments of the disclosure, terms related to orientation, such as “upper”, “lower”, “left”, “right”, “horizontal”, “vertical”, and the like, are only for the purpose of better understanding of the disclosure by those skilled in the art, and are not to be construed as limiting the disclosure.

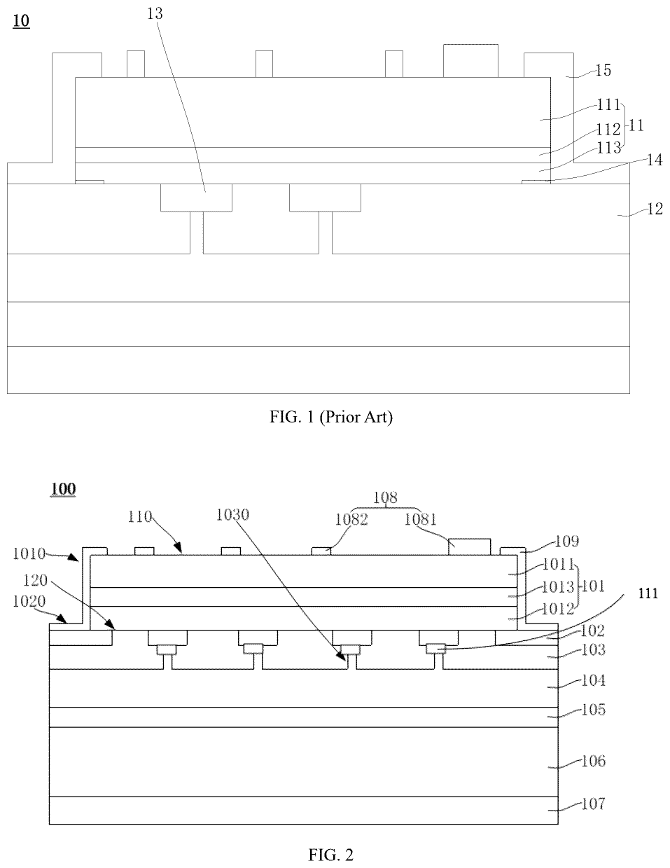

As shown in FIG. 1, in the related art, in a vertical LED chip 10, a semiconductor epitaxial stacking layer 11 includes a first semiconductor layer 111, an active layer 112 and a second semiconductor layer 113 sequentially stacked from top to bottom. An insulation layer 12 is disposed under the second semiconductor layer 113, and a current spreading layer 13 is formed between the insulation layer 12 and the second semiconductor layer 113. When the LED chip 10 shown in FIG. 1 is formed, the semiconductor epitaxial stacking layer 11 needs to be etched. There is no layer structure between the etched semiconductor epitaxial stacking layer 11 and the insulation layer 12 that can be used as an etching stop layer. Therefore, when etched to the insulation layer 12, etching gas etches the second semiconductor layer 113 inward along an interface between the second semiconductor layer 113 and the insulation layer 12, forming the gap 14 shown in FIG. 1 at the interface between the second semiconductor layer 113 and the insulation layer 12. The gap 14 will lead to uneven or poor coverage of a subsequently formed protection layer 15, affecting the durability of the device. In addition, the gap 14 will also cause the semiconductor epitaxial stacking layer 11 to peel off due to uneven force in the subsequent wiring process, resulting in device failure.

To solve the above problems, the disclosure provides a light-emitting diode and a light-emitting device, which will be described in detail in combination with embodiments and attached drawings.

### Embodiment 1

The embodiment provides a light-emitting diode 100. As shown in FIG. 2, the light-emitting diode 100 of the embodiment includes a semiconductor epitaxial stacking layer 101, a current spreading layer 102, an ohmic contact layer 111, a transparent dielectric layer 103, and a reflective layer 104. The semiconductor epitaxial stacking layer 101 has a first surface 110 and a second surface 120, a side of the first surface 110 is a light-emitting side of the light-emitting diode. Along a direction from the first surface 110 to the second surface 120, the semiconductor epitaxial stacking layer 101 includes a first conductive type semiconductor layer 1011, an active layer 1013 and a second conductive type semiconductor layer 1012 sequentially. The current spreading layer 102 is located on a side of the second surface 120 of the semiconductor epitaxial stacking layer 101, the ohmic contact layer 111 is located on a side of the current spreading layer 102 facing away from the second surface 120, the transparent dielectric layer 103 is located on the side of the ohmic contact layer away from the second surface 120, and the reflective layer 104 is located on a side of the ohmic contact layer 111 facing away from the second surface 120.

As shown in FIG. 2, the semiconductor epitaxial stacking layer 101 of the light-emitting diode 100 is formed into a mesa structure 1010, where the platform structure 1010 is a light-emitting region of the light-emitting diode 100, and a periphery of the mesa structure 1010 is an edge region 1020 of the light-emitting diode.

In an optional implementation, the semiconductor epitaxial stacking layer 101 can be formed on a growth substrate by physical vapor deposition (PVD), chemical vapor deposition (CVD), epitaxy growth technology, or atomic layer deposition (ALD). The first conductive type semiconductor layer 1011 and the second conductive type semiconductor layer 1012 are semiconductors with different conductivity types, electrical properties, and polarities, which provide electrons or holes depending on doped clements. For example, when the first conductive type semiconductor layer 1011 is n-type, the second conductive type semiconductor layer 1012 is p-type, the active layer 1013 is formed between the first conductive type semiconductor layer 1011 and the second conductive type semiconductor layer 1012, the electrons and holes are combined in the active layer 1013 driven by a current, the electrical energy is converted into light energy to emit light, and a wavelength of light emitted by the light-emitting diode 100 is adjusted by changing the physical and chemical composition of one or more layers of the epitaxial active layer 1013; and vice versa. In this embodiment, the light-emitting diode 100 with the first conductive type semiconductor layer 1011 as n-type and the second conductive type semiconductor layer 1012 as p-type is taken as an example.

The active layer 1013 is a region where electrons and hole recombine to provide light radiation, and different materials can be selected according to different emission wavelength, and that active layer 1013 can be a single heterostructure (SH), a double heterostructure (DH), double-sided double heterostructure (DDH), multiquantum well (MQW). The active layer 1013 includes a well layer and a barrier layer, where the barrier layer has a larger band gap than the well layer. By adjusting the composition ratio of the semiconductor material in the active layer 1013, different wavelengths of light are expected to be radiated. In this embodiment, the semiconductor epitaxial stacking layer 101 is a semiconductor material layer that can radiate ultraviolet, blue, green, yellow, red, infrared light, etc. Specifically, the semiconductor epitaxial stacking layer 101 can be a material of 200 nanometers (nm) to 950 nm, such as common nitrides, specifically such as a gallium nitride-based semiconductor epitaxial stacking layer, which is commonly doped with elements such as aluminum and indium. It mainly provides the radiation of wave band of 200-550 nm, or the common aluminum gallium indium phosphide (AlGaInP)-based or aluminum gallium arsenide (AlGaAs)-based semiconductor epitaxial stacking layer mainly provides the radiation of wave band of 550-950 nm. In order to improve the luminous efficiency, it can be achieved by changing the depth of the quantum wells, the number of pairs of quantum wells and quantum barriers, their thickness, and/or other characteristics in the active layer 1013. In this embodiment, the semiconductor epitaxial stacking layer 101 is specifically composed of AlGaInP or gallium arsenide (GaAs) based materials.

In order to improve the current expansion of the light-emitting diode 100, the current spreading layer 102 is arranged on the side of the second surface 120 of the semiconductor epitaxial stacking layer 101, that is, on the second conductive type semiconductor layer 1012. A material of the current spreading layer 102 can be GaP, AlGaAs, AlGaInP, etc. In this embodiment, the material of current spreading layer 102 is GaP, and a thickness is 0.02 μm to 1.5 μm. Specifically, the thickness of current spreading layer 102 is 0.02 μm to 0.8 μm. A doping concentration of the current spreading layer 102 is specifically 5E17-5E18/cm³. Since GaP has an absorption effect on the light radiated by the active layer 1013, in order to improve the light extraction efficiency of the light-emitting diode 100, this embodiment considers reducing the GaP material layer to reduce its absorption of light. As shown in FIG. 2, in the embodiment, the current spreading layer 102 includes a first part formed in a corresponding region of the mesa structure 1010, and a second part 1022 formed in an edge region 1020, and the first part and the second part 1022 are spaced apart from each other. The first part is formed as patterned structures, and the patterned structures are formed into multiple spaced platform regions 1021, which are formed by removing part of the current spreading layer 102, and the current spreading layer 102 around the platform regions 1021 is etched and removed.

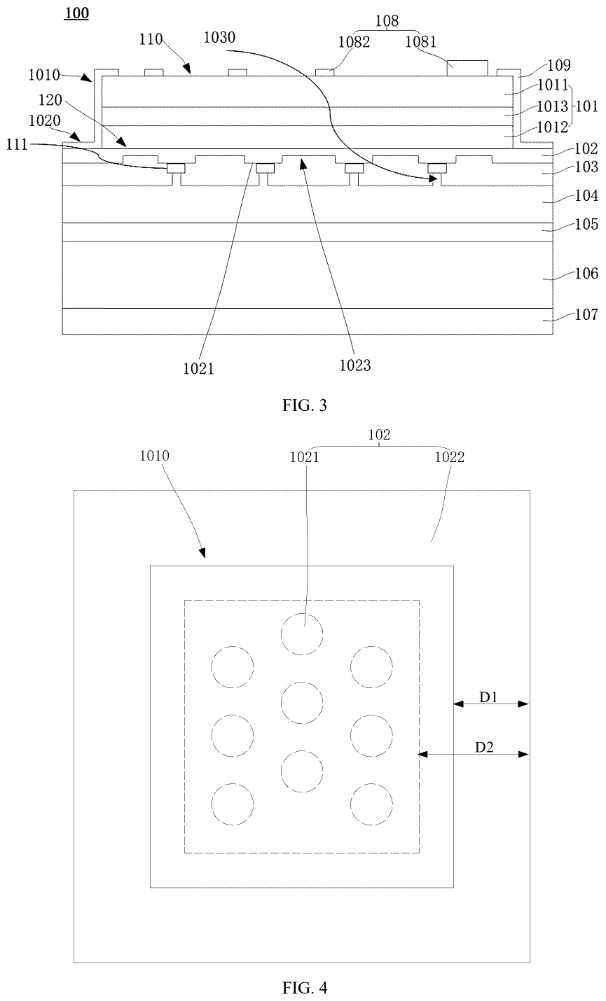

In an optional implementation, as shown in FIG. 3, part of the current spreading layer 102 remains around the platform regions 1021 to form recessed regions 1023, a depth of the recessed region 1023 is less than the thickness of the current spreading layer 102, for example, ⅓ to ⅔ of the thickness of the current spreading layer 102.

As shown in FIG. 2, in this embodiment, the current spreading layer 102 includes the first part formed in the corresponding region of the mesa structure 1010 and the second part 1022 formed in the edge region 1020. The first part is formed into patterned structures, which are formed into multiple spaced platform regions 1021. Specifically, a projection area of the platform region 1021 of the first part on the second surface 120 is 5%-50% of the projection area of the mesa structure 1010 on the second surface 120. The formation of platform regions 1021 removes part of the current spreading layer 102, reduces the light absorption, improves the light extraction efficiency of the light-emitting diode 100, and enables the current spreading layer 102 to ensure sufficient current expansion.

In an optional implementation, the second part 1022 of the current spreading layer 102 surrounds the mesa structure 1010 to form a region corresponding to the edge region 1020, and the side wall of the second part 1022 is flush with an outer side of the edge region 1020. That is, from a projection of the first surface 110 to the second surface 120, a distance between an edge of the mesa structure 1010 and an outer edge of the second part 1022 (where the outer edge of the second part 1022 is a side of the second part 1022 close to an edge of the outer side of the edge region 1020) is defined as D1, a width of the second part 1022 of the current spreading layer 102 (i.e., a span between an inner edge of the second part 1022 facing away from the edge of the outer side of the edge region 1020 and the outer edge of the second part 1022 close to of the edge of the outer side of the edge region 1020) is D2. In this embodiment, the width D2 is greater than or equal to the distance D1. Further, referring to FIG. 2 and FIG. 4, the width D2 is greater than the distance D1, that is, the second part 1022 of the current spreading layer 102 completely covers the edge region 1020 and extends from the edge region 1020 to below the second conductive type semiconductor layer 1012 in the region of the mesa structure 1010. In an embodiment, the difference between the width D2 and the distance D1 is greater than or equal to 1 μm, and further, between 1 μm and 20 μm.

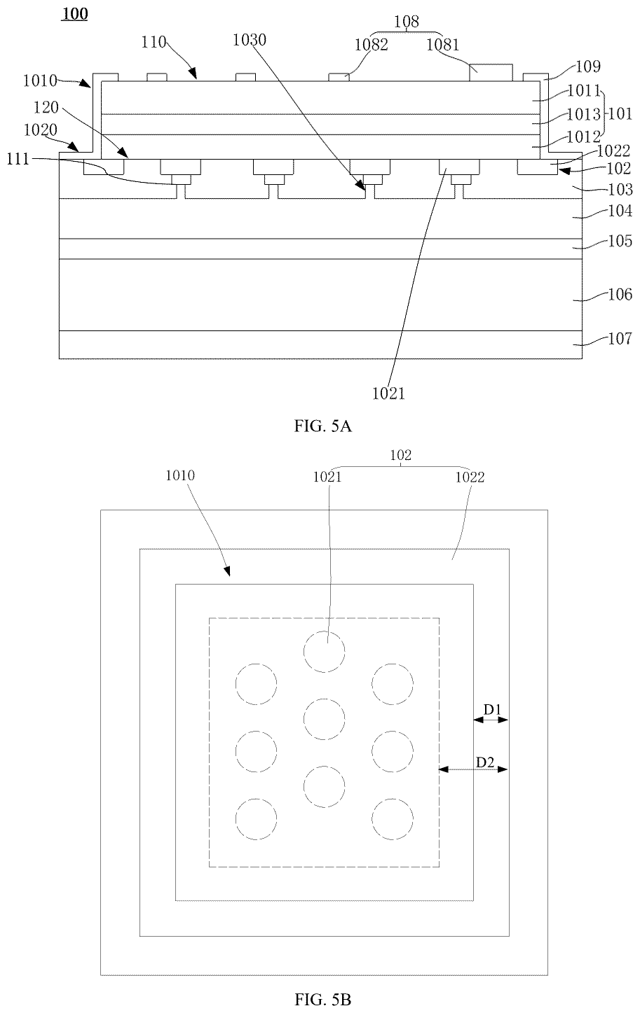

In an optional implementation, as shown in FIG. 5A and FIG. 5B, the second part 1022 of the current spreading layer 102 extends below the second conductive type semiconductor layer 1012 in the region of the mesa structure 1010, but does not completely cover the edge region 1020. That is, as shown in FIG. 5B, from a perspective of a top view of the light-emitting diode 100, an outer edge line of the second part 1022 of the current spreading layer 102 falls within the range of the edge region 1020. At this time, the distance D1 between the edge of the mesa structure 1010 and the outer edge of the second part 1022 is less than the width D2 of the second part 1022.

In an optional implementation, an ohmic contact layer 111 may also be formed above the first part of the current spreading layer 102 on the side of the second surface 120 of the semiconductor epitaxial stacking layer 101, and an ohmic contact is formed with the current spreading layer 102 through the ohmic contact layer 111. Specifically, the ohmic contact layer 111 is located above the platform regions 1021 of the first part, and the ohmic contact layer 111 can either completely cover the platform regions 1021 or partially cover the platform regions 1021. Therefore, the ohmic contact layer 111 and the current spreading layer 102 form patterned structures at the same time, which can also reduce the light absorption of the ohmic contact layer 111. The ohmic contact layer 111 is a transparent conductive layer, such as zinc oxide (ZnO), indium oxide (In₂O₃), tin dioxide (SnO₂), indium tin oxide (ITO), indium zinc oxide (IZO), gallium-doped zinc oxide (GZO) or any combination thereof. In this embodiment, the ohmic contact layer 111 is specifically ITO.

As shown in FIG. 2, the transparent dielectric layer 103 is formed on the side of the current spreading layer 102 facing away from the second surface 120 and is filled around the current spreading layer 10. Further, the transparent dielectric layer 103 does not form on the surface of the platform regions 202 of the current spreading layer 102. The transparent dielectric layer 103 defines multiple openings above the ohmic contact layer 111, and the openings are formed into multiple conductive through-holes 1030. The transparent dielectric layer 103 is fluoride, oxide, or nitride, specifically formed by at least one material of zinc oxide (ZnO), silicon dioxide (SiO₂), silicon oxide with variable x (SiOₓ), silicon oxynitride with variables x and y (SiOₓN_{y}), silicon nitride (Si₃N₄), aluminum oxide (Al₂O₃), titanium oxide with variable x (TiOₓ), magnesium fluoride (MgF), or gallium fluoride (GaF). The transparent dielectric layer 103 is used to reflect the light radiation of the active layer 1013 back to the semiconductor epitaxial stacking layer 101 or the light through the side wall. Therefore, the transparent dielectric layer 103 in direct contact with the semiconductor epitaxial stacking layer 101 is specifically a low-refractive index material to increase the probability of reflection of light radiation passing through the semiconductor epitaxial stacking layer 101 to the surface of the transparent dielectric layer 103. The refractive index of the transparent dielectric layer 103 is specifically below 1.5, such as silicon oxide, and a thickness of the transparent dielectric layer 103 is specifically above 100 nm, such as 100 nm to 1000 nm, specifically 100 nm to 900 nm, or more specifically 300 nm to 900 nm. The light transmittance of the transparent dielectric layer 103 is at least 70%, specifically greater than 80%, more specifically greater than 90%.

In an embodiment, the transparent dielectric layer 103 is a single layer or multiple layers of different materials or is composed of insulation layer materials of two different refractive indices repeatedly stacked. More specifically, an optical thickness of the transparent dielectric layer 103 is within the range of integer multiples of (emission wavelength/4).

The reflective layer 104 covers the transparent dielectric layer 103 and is filled into the conductive through-holes 1030, which is in contact with the ohmic contact layer 111 to realize the conduction and expansion of the current in the light-emitting diode 100. A cross-sectional area of the ohmic contact layer 111 is greater than a cross-sectional area of the conductive through-holes 1030 of the transparent dielectric layer 103, which can maximize the specular reflection area while ensuring the low voltage of the light-emitting diode 100, thereby improving the luminous brightness and luminous efficiency of the light-emitting diode 100. The reflective layer 104 has a reflectivity of more than 70% and is formed by at least one metal or alloy containing silver (Ag), nickel (Ni), aluminum (Al), rhodium (Rh), palladium (Pd), iridium (Ir), ruthenium (Ru), magnesium (Mg), titanium (Ti), chromium (Cr), zinc (Zn), platinum (Pt), gold (Au), and hafnium (Hf). In this embodiment, the reflective layer 104 is specifically Au or Ag. The reflective layer 104 can reflect the light radiated from the semiconductor epitaxial stacking layer 101 towards a side of a substrate 106 back to the semiconductor epitaxial stacking layer 101 and radiate out from a light-emitting side (i.e., the side of the first surface 110 of the semiconductor epitaxial stacking layer 101).

The conductive through-holes 1030 of the transparent dielectric layer 103 can be any possible shape such as circle, ellipse, polygon, etc. The side walls of the conductive through-hole 1030 can be vertical side walls or inclined side walls. The side wall of the opening of the transparent dielectric layer 103 is inclined, so that the reflective layer 104 can cover the side wall of the opening. In this situation, the inclined side wall can reflect the light radiated by the semiconductor epitaxial stacking layer 101 to the light-emitting surface.

Referring to FIG. 2, the side of the reflective layer 104 facing away from the second surface 120 is further provided with a substrate 106, a metal bonding layer 105 is disposed between the substrate 106 and the reflective layer 104, and the metal bonding layer 105 bonds the semiconductor epitaxial stacking layer 101 to the substrate 106. The metal bonding layer 105 can be any one or a combination of materials of metals such as Au, Sn, Ti, W, Ni, Pt, In, etc. The metal bonding layer 105 may be a single layer structure or a multi-layer structure. The substrate 106 is a conductive substrate, which can be used as a conductive Si substrate, a metal substrate or other conductive substrate.

Referring to FIG. 2, the first electrode 108 is electrically connected to the first conductive type semiconductor layer 1011 on the first surface 110 of the semiconductor epitaxial stacking layer 101. The first electrode 108 includes a pad electrode 1081 and multiple expansion electrodes 1082. The first electrode 108 can be of single, double or multilayer structure. In some optional implementations, the pad electrode 1081 can be designed into different shapes according to the actual needs, such as cylindrical shape or square or other polygon, and the pad electrode 1081 can be formed in any suitable position in an edge region, a middle region, etc. of the chip according to the needs of subsequent wiring, die bonding, etc. In an embodiment, the pad electrode 801 may include multiple regions formed on the same side of the chip; or the pad electrode 801 may include multiple regions formed on opposite sides of the chip. The extension electrodes 1082 may be formed in a predetermined pattern shape and, specifically, the extension electrodes 1082 may be a parallel strip structure, the end of which is electrically connected with the pad electrode 1081. The pad electrode 1081 and the expansion electrodes 1082 may be selected from germanium (Ge), Au, Ni, or any combination thereof, and may further include metal materials that achieve good ohmic contact with the semiconductor epitaxial stacking layer 101.

A second electrode 107 is formed on a side of the substrate 106 facing away from the metal bonding layer 105, and the second electrode 107 is formed on the substrate 106 in the form of full coverage. A material of the second electrode 107 includes metal material or metal alloy material, which can specifically include Au, Pt, GeAlNi, Ti, BeAu, GeAu, Al or ZnAu.

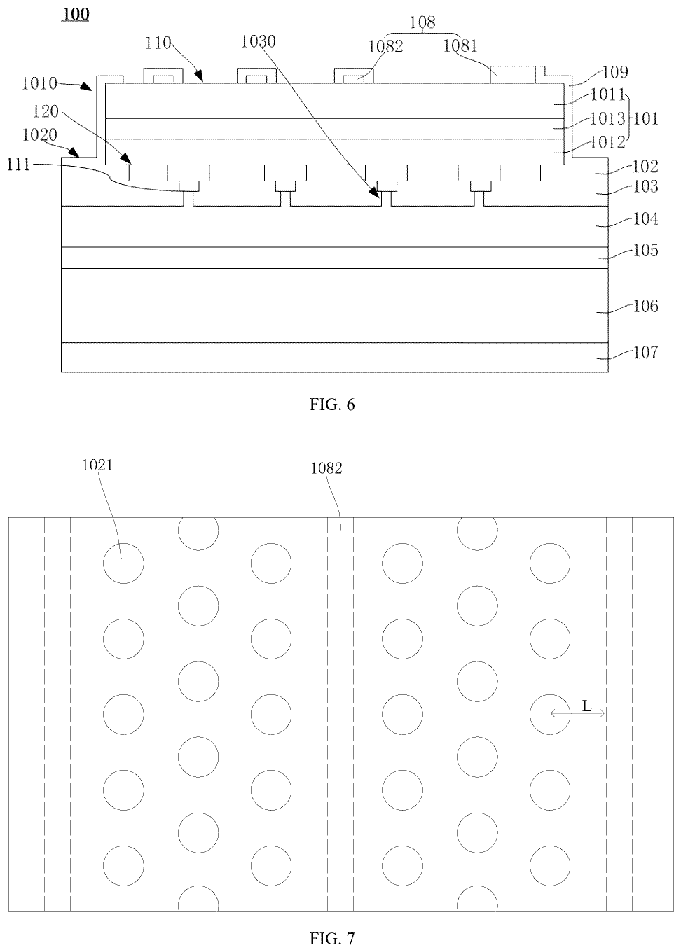

Referring to FIG. 2, the light-emitting diode 100 of the embodiment further includes a protective layer 109 covering the side wall and part of the surface of the mesa structure 1010 and the edge region 1020. The protective layer 109 can be SiO₂, SiOₓ, SiOₓN_{y}, or Si₃N₄, or a composite layer of the above materials. In an optional implementation, as shown in FIG. 6, the protective layer 109 not only covers the side wall and part of the surface of the mesa structure 1010 and the edge region 1020, but also covers the side wall and surface of the extension electrodes 1082 of the first electrode 108 and the side wall of the pad electrode 1081 of the first electrode 108. Further, the projection of the platform regions 1021 of the first part of the current spreading layer 102 on the first surface 110 does not coincide with the projection of the protective layer 109 on the first surface 110.

In this embodiment, when the etched semiconductor epitaxial stacking layer 101 forms the mesa structure 1010, the current spreading layer 102 of the edge region 1020 can be used as the etching stop layer. During the etching process, the current spreading layer 102 can be identified to accurately cut off the ICP signal. The etching accurately stops after the etching of the semiconductor epitaxial stacking layer 101 to prevent the formation of a side etching gap at the contact interface between the exposed semiconductor epitaxial stacking layer 101 and the transparent dielectric layer 103 after etching. Therefore, it can effectively improve the coverage of the protective layer 109 on the side wall of the mesa structure 1010, but also improve the force uniformity of the semiconductor epitaxial stacking layer 101 during subsequent wiring, prevent the semiconductor epitaxial stacking layer 101 stripping, and improve the yield of the light-emitting diode 100.

### Embodiment 2

The embodiment provides a light-emitting diode 100, which includes a semiconductor epitaxial stacking layer 101, a current spreading layer 102, an ohmic contact layer 111, a transparent dielectric layer 103, and a reflective layer 104. The semiconductor epitaxial stacking layer 101 has a first surface 110 and a second surface 120, a side of the first surface 110 is a light-emitting side of the light-emitting diode 100. Along a direction from the first surface 110 to the second surface 120, the semiconductor epitaxial stacking layer 101 includes a first conductive type semiconductor layer 1011, an active layer 1013 and a second conductive type semiconductor layer 1012 sequentially. The current spreading layer 102 is located on a side of the second surface 120 of the semiconductor epitaxial stacking layer 101, the ohmic contact layer 111 is located on a side of the current spreading layer 102 facing away from the second surface 120, the transparent dielectric layer 103 is located on the side of the ohmic contact layer away from the second surface 120, and the reflective layer 104 is located on a side of the ohmic contact layer 111 facing away from the second surface 120. The similarities with the embodiment 1 are not repeated herein, but the differences are as follows.

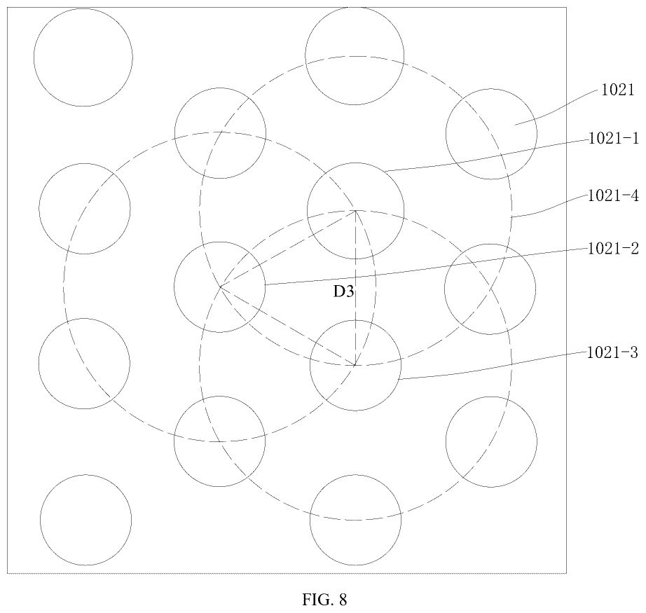

In this embodiment, as shown in FIG. 7 and FIG. 8, a distance between geometric centers of cross-sections of the platform regions 1021 of the current spreading layer 102 is equal, and the cross-section of the platform region 1021 of the current spreading layer 102 is a circle in shape. As shown in FIG. 8, taking three platform regions as an example, the distance D3 between the geometric centers of the adjacent first circular platform region 1021-1, the second circular platform region 1021-2 and the third circular platform region 1021-3 is the same. In an optional implementation, the distance D3 between the geometric centers of any two adjacent platform regions is 1.2 to 3.2 times a diameter of the circle and further 1.5 to 2.0 times the diameter of the circle. The distance definition enables to optimize the size and distribution of the platform regions 1021 to ensure good current spreading effect.

In an optional implementation, a circle is made with the geometric center of the first circular platform region 1021-1 as a center and the distance D3 as a radius to form a circumference 1021-4, and the geometric centers of 2k platform regions are located on the circumference 1021-4, where k is a natural number greater than or equal to 1. That is, the geometric centers of an even number of platform regions are located on the circumference 1021-4. Further, the geometric centers of the surrounding platform regions 1021 adjacent to the first circular platform region 1021-1 are located on the circumference 1021-4. This can ensure that when the current is diffused through each platform region 1021, the overlapping area of current expansion between any adjacent platform regions is equal, thus achieving the effect of uniform current diffusion.

In an optional implementation, as shown in FIG. 7, the projection of the platform regions 1021 of the first part of the current spreading layer 102 on the first surface 110 does not coincide with the projection of the first electrode 108 on the first surface 110. Further, as shown in FIG. 7, the projection of the platform regions 1021 of the current spreading layer 102 on the first surface 110 does not coincide with the projection of the first electrode 108 on the first surface 110. Further, as shown in FIG. 7, in the projection on the first surface 110, the minimum spacing distance between the projection of the geometric center of the platform region 1021 and the extension electrode 1082 is L, and the minimum spacing distance L is 1.2-3.2 times the diameter of the cross-section circle of the platform region 1021, and specifically 1.5-2.5 times.

This embodiment further defines that the distance between the geometric centers of adjacent platform regions 1021 in the current spreading layer 102 corresponding to the mesa structure 1010 is equal, that is, the geometric center of any platform region 1021 is a center of a circle, the distance between the geometric centers of adjacent platform regions 1021 is a radius of the circle, and the centers of adjacent platform regions 1021 are on the circle. Therefore, the adjacent platform regions 1021 forms a complementary pattern when the current expands. Taking one platform region 1021 as an example, the overlapping area of current expansion between any adjacent platform regions 1021 is equal, thus achieving the effect of uniform current diffusion.

### Embodiment 3

The embodiment provides a light-emitting diode 100, which includes a semiconductor epitaxial stacking layer 101, a current spreading layer 102, an ohmic contact layer 111, a transparent dielectric layer 103, and a reflective layer 104. The semiconductor epitaxial stacking layer 101 has a first surface 110 and a second surface 120, a side of the first surface 110 is a light-emitting side of the light-emitting diode 100. Along a direction from the first surface 110 to the second surface 120, the semiconductor epitaxial stacking layer 101 includes a first conductive type semiconductor layer 1011, an active layer 1013 and a second conductive type semiconductor layer 1012 sequentially. The current spreading layer 102 is located on a side of the second surface 120 of the semiconductor epitaxial stacking layer 101, the ohmic contact layer 111 is located on a side of the current spreading layer 102 facing away from the second surface 120, the transparent dielectric layer 103 is located on the side of the ohmic contact layer 111 facing away from the second surface 120, and the reflective layer 104 is located on a side of the ohmic contact layer 111 facing away from the second surface 120. The similarities with the embodiment 1 are not repeated herein, but the differences are as follows.

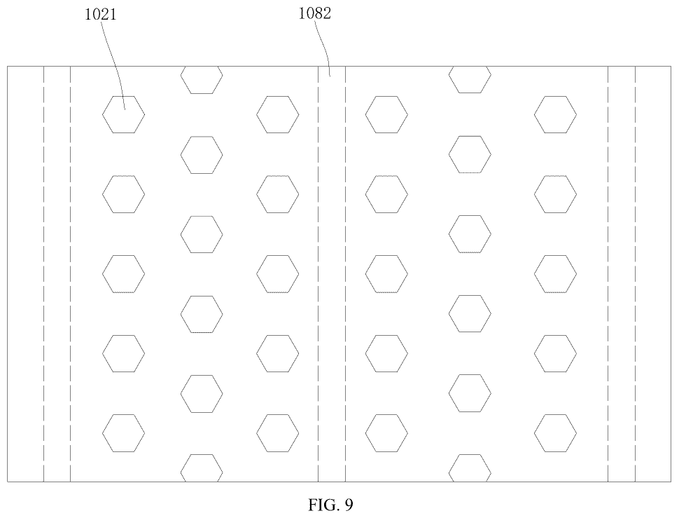

In this embodiment, a cross-section of the platform region 1021 of the current spreading layer 102 is a regular polygon, as shown in FIG. 9, which is a regular hexagon, and it can be understood that it can also be a square, a regular octagon, and other shapes.

The shape of the cross-section of the platform region 1021 of the current spreading layer 102 can be selected according to the specific structure of the light-emitting diode 100 and the material of the current spreading layer 102, so that the shape of the cross-section of the platform region 1021 of the current spreading layer 102 can be designed according to the specific light-emitting diode 100 to increase the applicability of the platform regions 1021.

### Embodiment 4

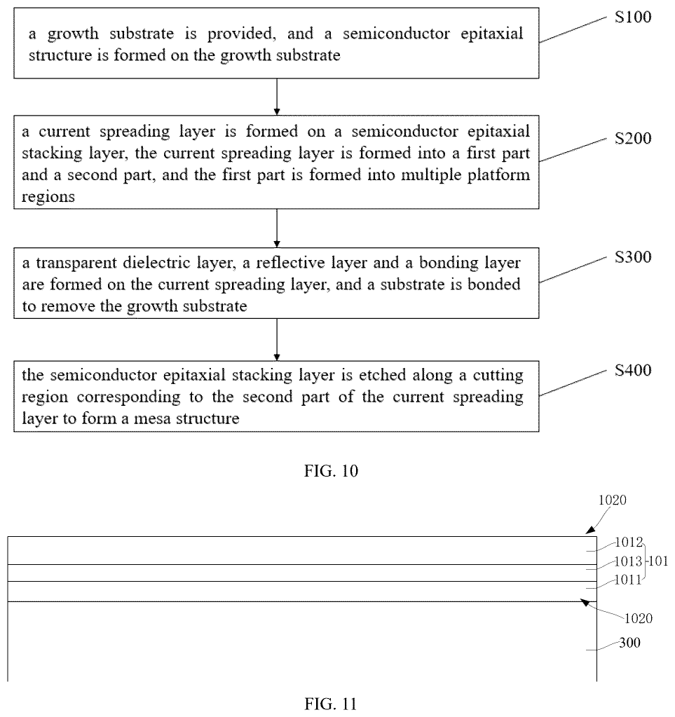

The embodiment provides a method for manufacturing a light-emitting diode by which any of the light-emitting diodes in the embodiments 1 to 3 can be obtained. As shown in FIG. 10, the method includes the following steps.
S100: a growth substrate is provided, and a semiconductor epitaxial structure is formed on the growth substrate.

In this embodiment, the growth substrate may be any substrate suitable for epitaxial growth, such as Si substrate, silicon carbide (SiC) substrate, silicon-on-insulator (SOI) substrate, sapphire substrate, etc. In this embodiment, the sapphire substrate is taken as an example. As shown in FIG. 11, the first conductive type semiconductor layer 1011, the active layer 1013 and the second conductive type semiconductor layer 1012 are successively grown on the growth substrate 300 to form the semiconductor epitaxial stacking layer 101. A side of the first conductive type semiconductor layer 1011 close to the growth substrate 300 is the first surface 110 of the semiconductor epitaxial stacking layer 101, and the side of the second conductive type semiconductor layer 1012 facing away from the growth substrate is the second surface 120 of the semiconductor epitaxial stacking layer 101. The semiconductor epitaxial stacking layer 101 can be described by reference to the embodiment 1 and will not be described herein.
S200: a current spreading layer is formed on the semiconductor epitaxial stacking layer, the current spreading layer is formed into a first part and a second part, and the first part is formed into multiple platform regions.

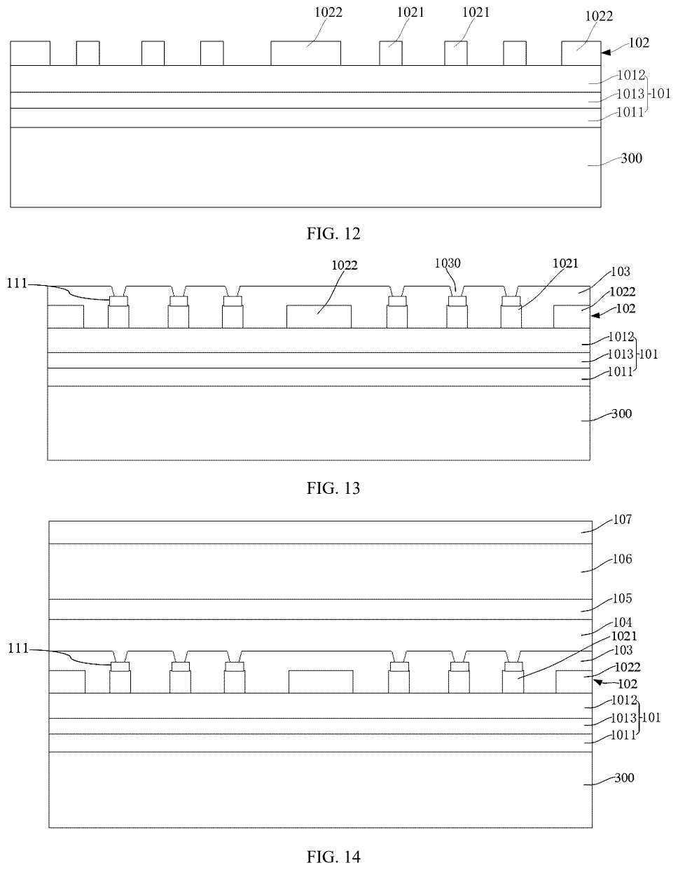

After forming the semiconductor epitaxial stacking layer 101, the current spreading layer 102 is formed on the side of the second surface 120, as shown in FIG. 12. The current spreading layer 102 can be GaP, AlGaAs, AlGaInP, etc. In this embodiment, the material of current spreading layer 102 is GaP, and the thickness is 0.02 μm-1.5 μm. Specifically, the thickness of current spreading layer 102 is 0.02 μm-0.8 μm. The doping concentration of the current spreading layer 102 is specifically 5E17-5E18/cm³. Since GaP has an absorption effect on the light radiated by the active layer 1013, the current spreading layer 102 is patterned, as shown in FIG. 12. In the patterning process, a part of the current spreading layer 102 is removed by etching to form the first part and the second part 1022 spaced apart from each other by current spreading, and the first part is formed as multiple platform regions 1021 spaced apart from each other. In an optional implementation, the current spreading layer 102 between the first part and the second part 1022 and between multiple platform regions 1021 is completely etched and removed.
S300: a transparent dielectric layer, a reflective layer and a bonding layer are formed on the current spreading layer, and a substrate is bonded to remove the growth substrate.

As shown in FIG. 13, the transparent dielectric layer 103 is first formed in the patterned current spreading layer 102 as shown in FIG. 12. As shown in FIG. 13, the transparent dielectric layer 103 is etched in the corresponding region of the platform regions 1021 of the first part of the current spreading layer 102 until the platform regions 1021 are exposed to form conductive through-holes 1030 corresponding to the platform regions 1021. As shown in FIG. 14, the reflective layer 104 is formed on the transparent dielectric layer 103. The reflective layer 104 is a metal reflective layer, which may, for example, be formed by at least one metal or alloy containing Ag, Ni, Al, Rh, Pd, Ir, Ru, Mg, Ti, Cr, Zn, Pt, Au, and Hf. The reflective layer 104 covers the transparent dielectric layer 103 and fills the conductive through-holes 1030 of the transparent dielectric layer 103 to electrically connected with the second conductive type semiconductor layer 1012 through the platform regions 1021 of the current spreading layer 102. It can be understood that before forming the reflective layer 104, the ohmic contact layer 111 is formed on the platform regions 1021.

As shown in FIG. 14, the bonding layer 105 is formed on the reflective layer 104, and the bonding layer 105 is also a metal layer. The substrate 106 is bonded on the bonding layer 105, and the bonding layer 105 can be any one or a combination of materials of metals such as Au, Sn, Ti, W, Ni, Pt, In, etc. The metal bonding layer 105 can be a single layer structure or a multi-layer structure. The substrate 106 is a conductive substrate, which can be used as a conductive Si substrate, a metal substrate or other conductive substrate with conductive properties can be selected.

After bonding the substrate 106, a metal layer is deposited on the surface of the substrate 106 as the second electrode 107 electrically connected to the second conductive type semiconductor layer 1012.

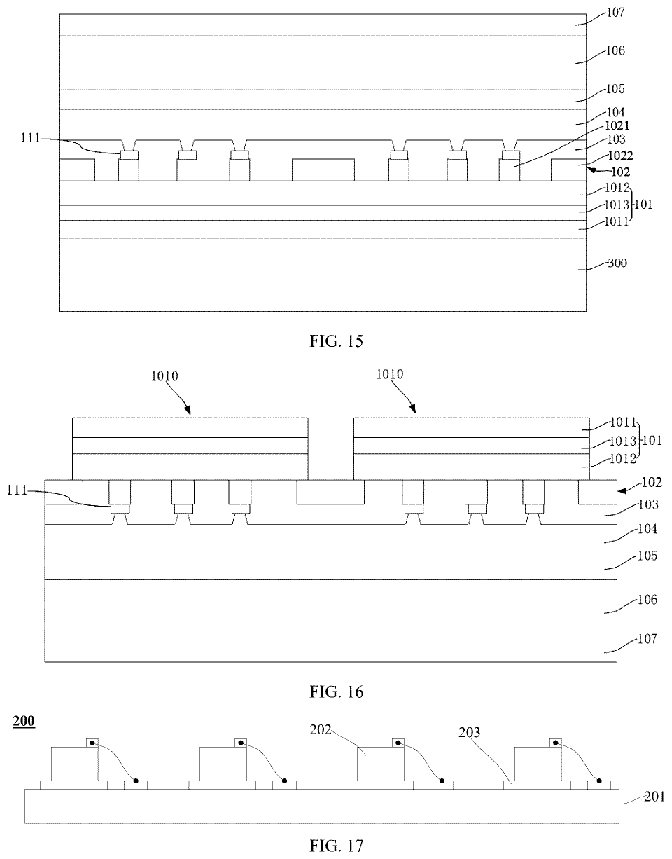

After that, as shown in FIG. 15, the growth substrate 300 is removed and the structure shown in FIG. 14 is inverted, so that the first surface 110 of the semiconductor epitaxial stacking layer 101 is exposed upward.
S400: the semiconductor epitaxial stacking layer is etched along a cutting region corresponding to the second part of the current spreading layer to form a mesa structure.

As shown in FIG. 16, the region corresponding to the second part 1022 of the current spreading layer 102 is defined as the cutting region. For example, the semiconductor epitaxial stacking layer 101 is etched along the cutting region using the ICP etching process until the current spreading layer 102 stops etched. In this process, the second part 1022 of the current spreading layer 102 can be accurately identified, so that the ICP signal can be accurately cut off when the current spreading layer 102 is identified, so that the etching process can be accurately stopped after the semiconductor epitaxial stacking layer 101 is etched to prevent the formation of a side etching gap at the contact interface between the exposed semiconductor epitaxial stacking layer 101 and the transparent dielectric layer 103 after etching. The etched semiconductor epitaxial stacking layer 101 forms multiple mesa structures 1010, and the multiple mesa structures 1010 are the light-emitting region.

The structure shown in FIG. 16 is then separated along the cutting region to obtain a single light-emitting unit with a single mesa structure 1010. A suitable cutting region can also be selected to separate the structure shown in FIG. 16 to obtain a light-emitting unit including multiple mesa structures 1010. In an embodiment, before separating the structure shown in FIG. 16, referring to FIG. 2, the first electrode 108 electrically connected to the first conductive type semiconductor layer 1011 can be formed on the mesa structure 1010, and the protective layer 109 covering the surface and side walls of the mesa structure 1010 and the cutting region can be formed.

### Embodiment 5

The embodiment provides a light-emitting device, as shown in FIG. 17, includes a circuit board 201 and at least one light-emitting element 202 fixed to the circuit board 201. The light-emitting element 202 includes any one or more combinations of the light-emitting diodes 100 provided by the above embodiments 1 to 3 of the disclosure. As shown in FIG. 10, one electrode of the light-emitting diode 100 is directly and fixedly connected to a wire layer 203 of the circuit board 201 through welding and other processes, and the other electrode is connected to the wire layer 203 of the circuit board 201 through the wiring process by a gold wire. Since the light-emitting device 200 includes any one or more combinations of the light-emitting diodes provided by the embodiments 1 to 3, it has a good light-emitting effect and better reliability at the same time.

The above embodiments are illustrative only of the principle and efficacy of the disclosure and are not used to limit the disclosure, and those skilled in the art may make various modifications and variations without deviating from the spirit and scope of the disclosure, and such modifications and variations fall within the limits of the appended claims.

What is claimed is:

1. A light-emitting diode, comprising:
a semiconductor epitaxial stacking layer, having a first surface and a second surface opposite to each other, wherein the semiconductor epitaxial stacking layer comprises: a first conductive type semiconductor layer, an active layer and a second conductive type semiconductor layer along a direction from the first surface to the second surface, the first surface is a light-emitting surface, the semiconductor epitaxial stacking layer forms a mesa structure, and the mesa structure is a light-emitting region of the light-emitting diode;
a current spreading layer, located on a side of the second surface of the semiconductor epitaxial stacking layer, wherein the current spreading layer comprises a first part formed in a corresponding region of the mesa structure and a second part formed in an edge region of a periphery of the mesa structure, the first part is formed as patterned structures, and the patterned structures are platform regions;
an ohmic contact layer, located on a side of the platform regions facing away from the second surface;
a transparent dielectric layer, located on a side of the ohmic contact layer facing away from the semiconductor epitaxial stacking layer and filling recessed regions, wherein the transparent dielectric layer defines a plurality of openings to form a plurality of conductive through-holes; and
a reflective layer, disposed on the transparent dielectric layer and filled into the plurality of conductive through-holes to form an electrical connection with the ohmic contact layer.

2. The light-emitting diode as claimed in claim 1, wherein a distance D1 between an edge of the mesa structure and an outer edge of the second part of the current spreading layer on a projection along the direction of the first surface to the second surface, a width of the second part of the current spreading layer is D2, and the width D2 is greater than or equal to the distance D1.

3. The light-emitting diode as claimed in claim 2, wherein a difference between the width D2 and the distance D1 is in a range of 1 micrometer (μm) and 20 μm.

4. The light-emitting diode as claimed in claim 1, further comprising a protective layer, formed on a side wall and a part of a surface of the mesa structure and covering the edge region of the mesa structure.

5. The light-emitting diode as claimed in claim 4, wherein a projection of the platform regions of the first part of the current spreading layer on the first surface does not coincide with a projection of the protective layer on the first surface.

6. The light-emitting diode as claimed in claim 1, wherein a distance between geometric centers of any adjacent two of the platform regions of the first part is equal.

7. The light-emitting diode as claimed in claim 1, wherein a cross-section of each platform region of the first part is circular or regular polygon.

8. The light-emitting diode as claimed in claim 1, wherein a distance D3 between geometric centers of any adjacent two of the platform regions of the first part is in a range of 10 μm to 30 μm.

9. The light-emitting diode as claimed in claim 1, wherein a distance between geometric centers of any adjacent two of the platform regions of the first part is D3, with the geometric center of any one of the platform regions as a center of a circle and the distance D3 as a radius of the circle, and geometric centers of 2k platform regions is located on the circle, where k is a natural number greater than or equal to 1.

10. The light-emitting diode as claimed in claim 1, wherein a cross-section of each platform region is a circle in shape, and a distance D3 between geometric centers of any adjacent two of the platform regions is in a range of 1.2 to 3.2 times a diameter of the circle.

11. The light-emitting diode as claimed in claim 1, wherein a projection area of the platform regions of the first part on the second surface is in a range of 5% to 50% of a projection area of the mesa structure on the second surface.

12. The light-emitting diode as claimed in claim 1, wherein the recessed regions are formed among the platform regions, and a depth of each recessed region is in a range of ⅓ to ⅔ of a thickness of the current spreading layer.

13. The light-emitting diode as claimed in claim 1, further comprising: a first electrode located on a side of the first surface and electrically connected to the first conductive type semiconductor layer; wherein the first electrode comprises a pad electrode and expansion electrodes, the expansion electrodes are distributed on the side of the first surface, and when projected toward the first surface, a projection of the expansion electrodes and a projection of the pad electrode do not coincide with a projection of the first part of the current spreading layer.

14. The light-emitting diode as claimed in claim 13, wherein a cross-section of each platform region is a circle in shape, and a minimum distance between the projection of the expansion electrodes and a projection of geometric centers of the platform regions is in a range of 1.2 to 3.2 times a diameter of the circle.

15. The light-emitting diode as claimed in claim 1, further comprising:
a substrate, located on a side of the reflective layer facing away from the second surface;
a metal bonding layer, located between the substrate and the reflective layer; and
a second electrode, located on a side of the substrate facing away from the second surface and electrically connected with the second conductive type semiconductor layer.

16. The light-emitting diode as claimed in claim 1, wherein side walls of the platform regions are vertical side walls.

17. The light-emitting diode as claimed in claim 1, wherein side walls of the platform regions are inclined side walls.

18. The light-emitting diode as claimed in claim 17, wherein an opening size of a side of the platform regions facing away from the second surface is greater than a bottom size of a side of the platform regions close to the second surface.

19. A light-emitting device, comprising: a circuit board and at least one light-emitting element located on the circuit board, wherein the at least one light-emitting element comprises the light-emitting diode as claimed in in claim 1 with at least one in quantity.

20. The light-emitting device as claimed in claim 19, further comprising a wire layer, wherein the light-emitting diode is fixed to the wire layer on the circuit board.
